(19) United States
(12) Patent Application Publication
(10) Pub. No.: US 2022/0075409 A1
(43) Pub. Date: Mar. 10, 2022

(54) FOLDABLE ELECTRONIC DEVICE

(71) Applicants: Inventec (Pudong) Technology Corp., Shanghai (CN); Inventec Corporation, Taipei (TW)

(72) Inventors: Chih-Kai Yang, Taipei (TW); Yi-Lun Cheng, Taipei (TW); Feng-Kuan Lee, Taipei (TW); Wei-Yi Lin, Taipei (TW); Sheng-Chieh Hsu, Taipei (TW); Meng-Lung Chiang, Taipei (TW)

(21) Appl. No.: 16/952,108

(22) Filed: Nov. 19, 2020

(30) Foreign Application Priority Data
Sep. 9, 2020 (CN) 202010938195.X

(51) Int. Cl. G06F 1/16; G06F 1/20

(52) U.S. Cl. CPC G06F 1/1616; G06F 1/1681; G06F 1/203

(57) ABSTRACT

A foldable electronic device includes a first housing, a second housing, a pivot structure, a heat conducting member, a first heat pipe and a second heat pipe. The pivot structure pivotally connects the first housing to the second housing. The heat conducting member is disposed in the pivot structure. An end of the first heat pipe is pivotally connected to the heat conducting member and another end of the first heat pipe is fixed on the first housing. An end of the second heat pipe is pivotally connected to the heat conducting member and another end of the second heat pipe is fixed on the second housing.

### BACKGROUND OF THE INVENTION

### 1. Field of the Invention

The invention relates to a foldable electronic device and, more particularly, to a foldable electronic device equipped with a heat dissipating structure having two rotating shafts.

### 2. Description of the Prior Art

As technology advances and develops, various foldable electronic devices, such as a notebook computer, a mobile phone, etc. have been considered a necessity by a lot of people in daily life. When an electronic device is operating, the current in circuit will generate unnecessary heat due to impedance. If the heat is accumulated in the electronic components of the electronic device without dissipating immediately, the electronic components may get damage due to the accumulated heat. Therefore, most of the foldable electronic devices are equipped with a heat dissipating structure for heat dissipation. The heat dissipating structure of the conventional foldable electronic device consists of two heat pipes. The two heat pipes are fixed on a cover and a base of the foldable electronic device, respectively. Since the two heat pipes are pivotally connected to each other to form one single rotating shaft, a rotating angle of the cover with respect to the base is restrained to be smaller than 180 degrees. In other words, the cover cannot rotate with respect to the base over 180 degrees, such that the use of the foldable electronic device is also restrained.

### SUMMARY OF THE INVENTION

The invention provides a foldable electronic device equipped with a heat dissipating structure having two rotating shafts, so as to solve the aforesaid problems.

According to an embodiment of the invention, a foldable electronic device comprises a first housing, a second housing, a pivot structure, a heat conducting member, a first heat pipe and a second heat pipe. The pivot structure pivotally connects the first housing to the second housing. The heat conducting member is disposed in the pivot structure. An end of the first heat pipe is pivotally connected to the heat conducting member and another end of the first heat pipe is fixed on the first housing. An end of the second heat pipe is pivotally connected to the heat conducting member and another end of the second heat pipe is fixed on the second housing.

As mentioned in the above, the invention pivotally connects the first heat pipe and the second heat pipe to the heat conducting member to forma heat dissipating structure having two rotating shafts. When the first housing rotates with respect to the second housing, the heat conducting member rotates with respect to the first heat pipe and the second heat pipe, together with the pivot structure. Accordingly, the first housing is able to rotate with respect to the second housing over 180 degrees (e.g. 360 degrees), so as to improve the use of the foldable electronic device for different operation modes.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic side view illustrating a foldable electronic device according to an embodiment of the invention.

FIG. 2 is a schematic side view illustrating that the first housing shown in FIG. 1 rotates with respect to the second housing with 90 degrees.

FIG. 3 is a schematic side view illustrating that the first housing shown in FIG. 1 rotates with respect to the second housing with 180 degrees.

FIG. 4 is a schematic side view illustrating that the first housing shown in FIG. 1 rotates with respect to the second housing with 270 degrees.

FIG. 5 is a schematic side view illustrating that the first housing shown in FIG. 1 rotates with respect to the second housing with 360 degrees.

FIG. 6 is a schematic assembly view illustrating the heat conducting member, the first heat pipe and the second heat pipe shown in FIG. 1.

FIG. 7 is a schematic assembly view illustrating a heat conducting member, a first heat pipe and a second heat pipe according to another embodiment of the invention.

FIG. 8 is a schematic assembly view illustrating a heat conducting member, a first heat pipe and a second heat pipe according to another embodiment of the invention.

FIG. 9 is a schematic assembly view illustrating a heat conducting member, a first heat pipe and a second heat pipe according to another embodiment of the invention.

FIG. 10 is a schematic assembly view illustrating a heat conducting member, a first heat pipe and a second heat pipe according to another embodiment of the invention.

FIG. 11 is a schematic assembly view illustrating a heat conducting member, a first heat pipe and a second heat pipe according to another embodiment of the invention.

FIG. 12 is a schematic assembly view illustrating a heat conducting member, a first heat pipe and a second heat pipe according to another embodiment of the invention.

### DETAILED DESCRIPTION

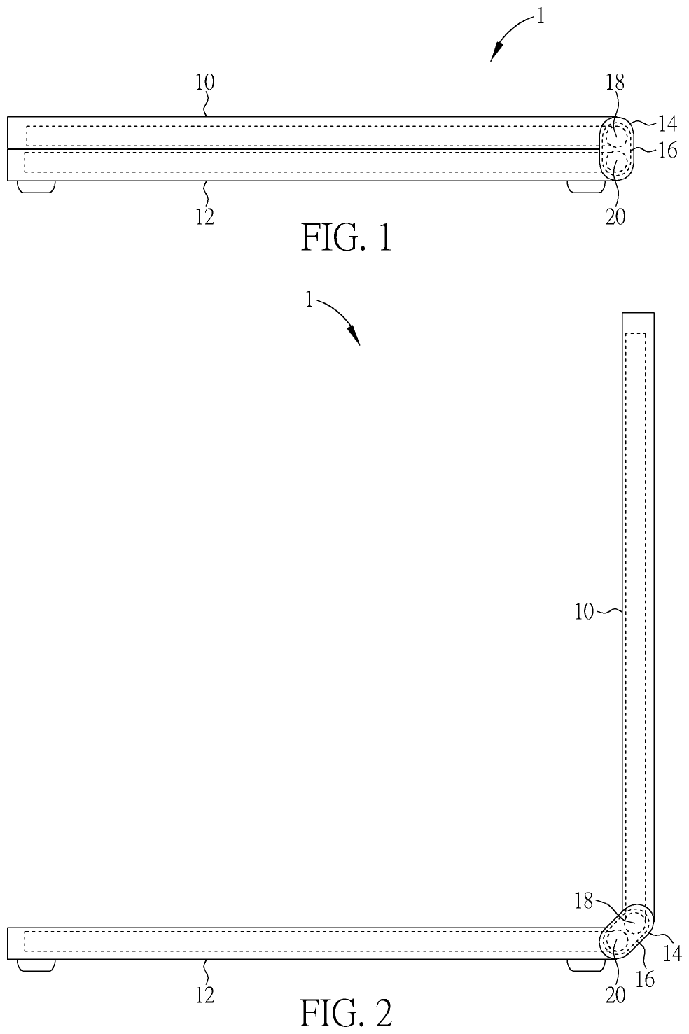

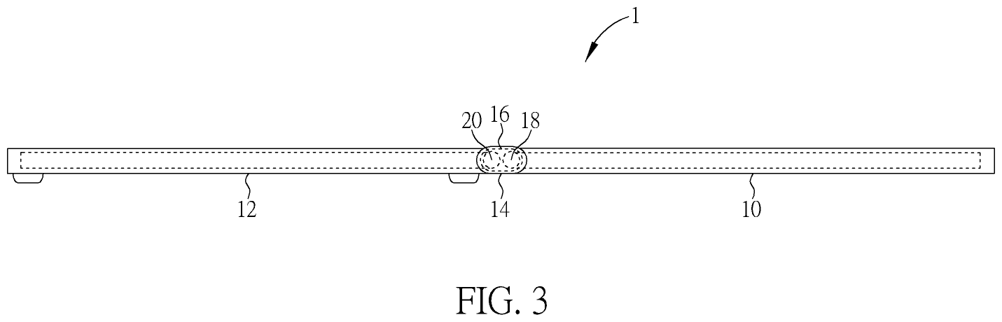

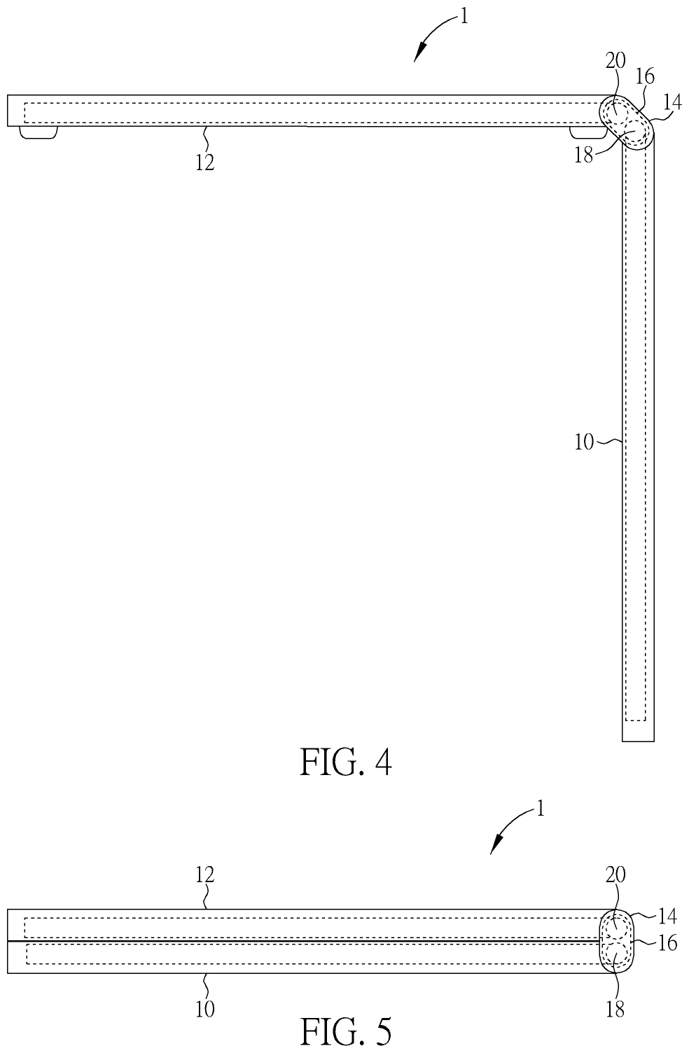

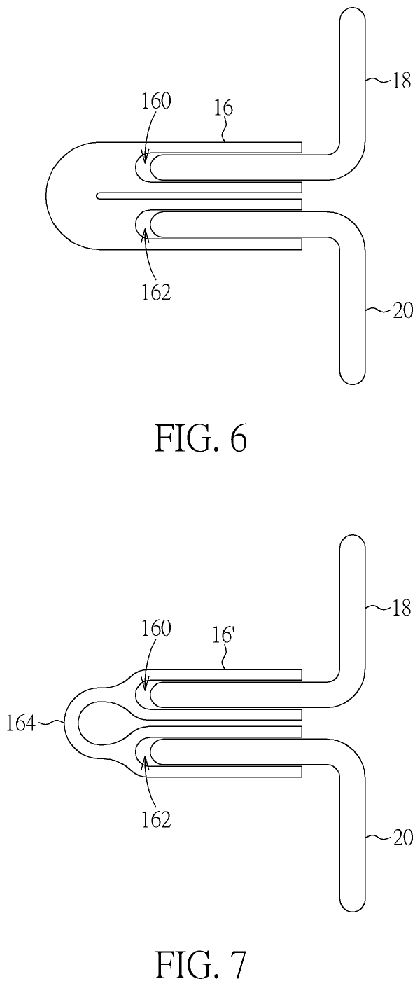

Referring to FIGS. 1 to 6, FIG. 1 is a schematic side view illustrating a foldable electronic device 1 according to an embodiment of the invention, FIG. 2 is a schematic side view illustrating that the first housing 10 shown in FIG. 1 rotates with respect to the second housing 12 with 90 degrees, FIG. 3 is a schematic side view illustrating that the first housing 10 shown in FIG. 1 rotates with respect to the second housing 12 with 180 degrees, FIG. 4 is a schematic side view illustrating that the first housing 10 shown in FIG. 1 rotates with respect to the second housing 12 with 270 degrees, FIG. 5 is a schematic side view illustrating that the first housing 10 shown in FIG. 1 rotates with respect to the second housing 12 with 360 degrees, and FIG. 6 is a schematic assembly view illustrating the heat conducting member 16, the first heat pipe 18 and the second heat pipe 20 shown in FIG. 1.

As shown in FIGS. 1 to 6, the foldable electronic device 1 comprises a first housing 10, a second housing 12, a pivot structure 14, a heat conducting member 16, a first heat pipe 18 and a second heat pipe 20. In this embodiment, the foldable electronic device 1 may be, but not limited to, a notebook computer. When the foldable electronic device 1 is a notebook computer, the first housing 10 may be a cover of the notebook computer and the second housing 12 may be abase of the notebook computer. In general, the foldable electronic device 1 may be further equipped with some necessary hardware or software components for specific purposes, such as processor, display, circuit board, memory, power supply, application, communication module, etc., and it depends on practical applications.

The pivot structure 14 pivotally connects the first housing 10 to the second housing 12, the first housing 10 may be closed (as shown in FIG. 1) or opened (as shown in FIGS. 2 to 5) with respect to the second housing 12. In practical applications, the pivot structure 14 may be, but not limited to, a hinge. The heat conducting member 16 is disposed in the pivot structure 14, such that the heat conducting member 16 is able to rotate together with the pivot structure 14.

An end of the first heat pipe 18 is pivotally connected to the heat conducting member 16 and another end of the first heat pipe 18 is fixed on the first housing 10. An end of the second heat pipe 20 is pivotally connected to the heat conducting member 16 and another end of the second heat pipe 20 is fixed on the second housing 12. In this embodiment, the heat conducting member 16 may be a U-shaped heat pipe. As shown in FIG. 6, the heat conducting member 16 has a first hole 160 and a second hole 162. An end of the first heat pipe 18 is inserted into the first hole 160 and an end of the second heat pipe 20 is inserted into the second hole 162, such that the first heat pipe 18 and the second heat pipe 20 are pivotally connected to the heat conducting member 16 to form a heat dissipating structure having two rotating shafts.

When the first housing 10 rotates with respect to the second housing 12, the heat conducting member 16 rotates with respect to the first heat pipe 18 and the second heat pipe 20, together with the pivot structure 14. Accordingly, the first housing 10 is able to rotate with respect to the second housing 12 between 0 degrees and 360 degrees, as shown in FIGS. 1 to 5. Since the first housing 10 is able to rotate with respect to the second housing 12 over 180 degrees (e.g. 360 degrees), the invention can improve the use of the foldable electronic device 1 for different operation modes.

Referring to FIG. 7, FIG. 7 is a schematic assembly view illustrating a heat conducting member 16′, a first heat pipe 18 and a second heat pipe 20 according to another embodiment of the invention. As shown in FIG. 7, the heat conducting member 16′ is also a U-shaped heat pipe. The aforesaid heat conducting member 16 may be replaced by the heat conducting member 16′. The main difference between the heat conducting member 16′ and the aforesaid heat conducting member 16 is that the heat conducting member 16′ has a tapered bending portion 164. The tapered bending portion 164 is not easy to crack during a bending process, such that the yield rate of heat conducting member 16′ can be improved effectively.

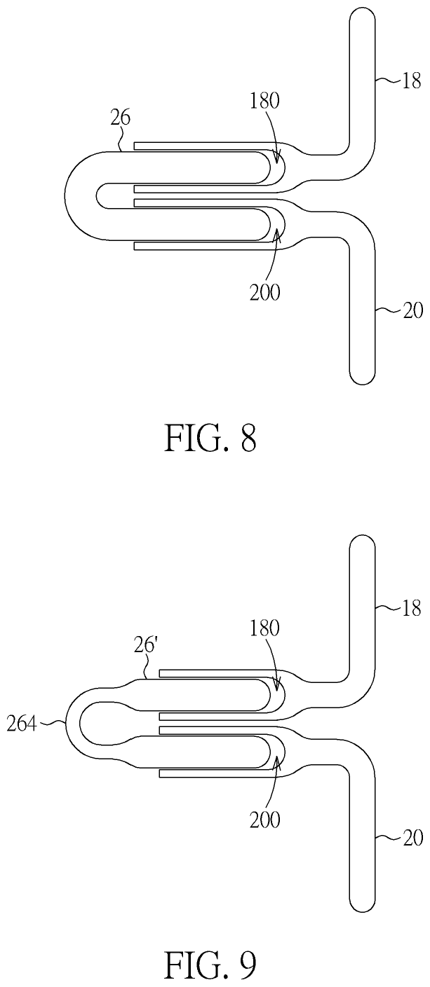

Referring to FIG. 8, FIG. 8 is a schematic assembly view illustrating a heat conducting member 26, a first heat pipe 18 and a second heat pipe 20 according to another embodiment of the invention. As shown in FIG. 8, the heat conducting member 26 is also a U-shaped heat pipe. The aforesaid heat conducting member 16 may be replaced by the heat conducting member 26. The main difference between the heat conducting member 26 and the aforesaid heat conducting member 16 is that both ends of the heat conducting member 26 do not have holes. In this embodiment, an end of the first heat pipe 18 has a first hole 180 and an end of the second heat pipe 20 has a second hole 200. An end of the heat conducting member 26 is inserted into the first hole 180 and another end of the heat conducting member 26 is inserted into the second hole 200, such that the first heat pipe 18 and the second heat pipe 20 are pivotally connected to the heat conducting member 26 to form a heat dissipating structure having two rotating shafts.

Referring to FIG. 9, FIG. 9 is a schematic assembly view illustrating a heat conducting member 26′, a first heat pipe 18 and a second heat pipe 20 according to another embodiment of the invention. As shown in FIG. 9, the heat conducting member 26′ is also a U-shaped heat pipe. The aforesaid heat conducting member 16 may be replaced by the heat conducting member 26′. The main difference between the heat conducting member 26′ and the aforesaid heat conducting member 26 is that the heat conducting member 26′ has a tapered bending portion 264. The tapered bending portion 264 is not easy to crack during a bending process, such that the yield rate of heat conducting member 26′ can be improved effectively.

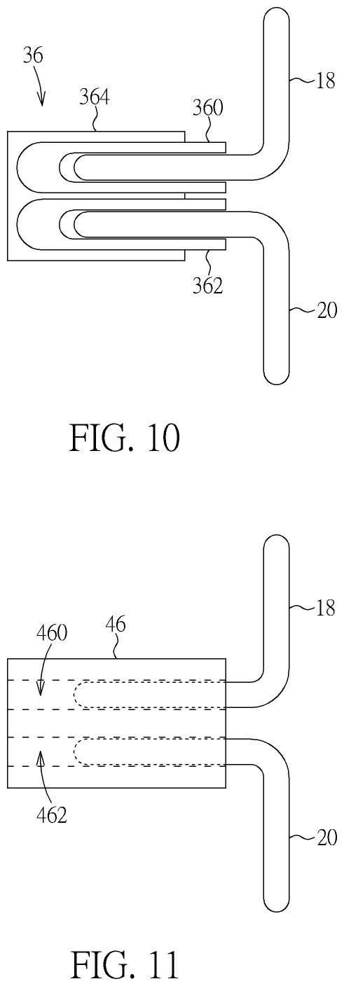

Referring to FIG. 10, FIG. 10 is a schematic assembly view illustrating a heat conducting member 36, a first heat pipe 18 and a second heat pipe 20 according to another embodiment of the invention. The aforesaid heat conducting member 16 may be replaced by the heat conducting member 36. The main difference between the heat conducting member 36 and the aforesaid heat conducting member 16 is that the heat conducting member 36 comprises a first sleeve 360, a second sleeve 362 and a base 364, as shown in FIG. 10. The first sleeve 360 and the second sleeve 362 are disposed on the base 364. In practical applications, the first sleeve 360 and the second sleeve 362 may be heat pipes with holes and the base 364 may be a metal plate. An end of the first heat pipe 18 is inserted into the first sleeve 360 and an end of the second heat pipe 20 is inserted into the second sleeve 362, such that the first heat pipe 18 and the second heat pipe 20 are pivotally connected to the heat conducting member 36 to form a heat dissipating structure having two rotating shafts.

Referring to FIG. 11, FIG. 11 is a schematic assembly view illustrating a heat conducting member 46, a first heat pipe 18 and a second heat pipe 20 according to another embodiment of the invention. The aforesaid heat conducting member 16 may be replaced by the heat conducting member 46. The main difference between the heat conducting member 46 and the aforesaid heat conducting member 16 is that the heat conducting member 46 is a metal block, as shown in FIG. 11. The heat conducting member 46 has a first hole 460 and a second hole 462. In practical applications, the heat conducting member 46 may be manufactured by an extrusion process, such that the first hole 460 and the second hole 462 penetrate the heat conducting member 46. Needless to say, the heat conducting member 46 may also be manufactured by other processes, such that the first hole 460 and the second hole 462 do not penetrate the heat conducting member 46. An end of the first heat pipe 18 is inserted into the first hole 460 and an end of the second heat pipe 20 is inserted into the second hole 462, such that the first heat pipe 18 and the second heat pipe 20 are pivotally connected to the heat conducting member 46 to form a heat dissipating structure having two rotating shafts.

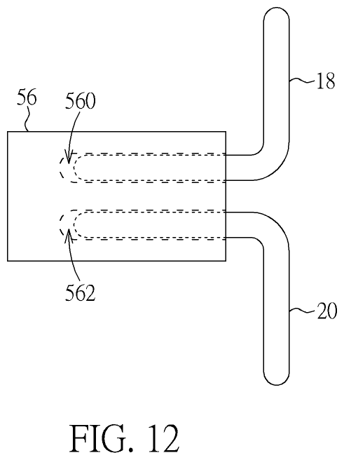

Referring to FIG. 12, FIG. 12 is a schematic assembly view illustrating a heat conducting member 56, a first heat pipe 18 and a second heat pipe 20 according to another embodiment of the invention. The aforesaid heat conducting member 16 may be replaced by the heat conducting member 56. The main difference between the heat conducting member 56 and the aforesaid heat conducting member 16 is that the heat conducting member 56 is a vapor chamber, as shown in FIG. 12. The heat conducting member 56 has a first hole 560 and a second hole 562. In this embodiment, the first hole 560 and the second hole 562 do not penetrate the heat conducting member 56. In another embodiment, the first hole 560 and the second hole 562 may penetrate the heat conducting member 56 according to practical applications. An end of the first heat pipe 18 is inserted into the first hole 560 and an end of the second heat pipe 20 is inserted into the second hole 562, such that the first heat pipe 18 and the second heat pipe 20 are pivotally connected to the heat conducting member 56 to form a heat dissipating structure having two rotating shafts.

As mentioned in the above, the invention pivotally connects the first heat pipe and the second heat pipe to the heat conducting member to forma heat dissipating structure having two rotating shafts. When the first housing rotates with respect to the second housing, the heat conducting member rotates with respect to the first heat pipe and the second heat pipe, together with the pivot structure. Accordingly, the first housing is able to rotate with respect to the second housing over 180 degrees (e.g. 360 degrees), so as to improve the use of the foldable electronic device for different operation modes.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A foldable electronic device comprising:
a first housing;
a second housing;
a pivot structure pivotally connecting the first housing to the second housing;
a heat conducting member disposed in the pivot structure;
a first heat pipe, an end of the first heat pipe being pivotally connected to the heat conducting member, another end of the first heat pipe being fixed on the first housing; and
a second heat pipe, an end of the second heat pipe being pivotally connected to the heat conducting member, another end of the second heat pipe being fixed on the second housing.

2. The foldable electronic device of claim 1, wherein the heat conducting member is a U-shaped heat pipe, the heat conducting member has a first hole and a second hole, an end of the first heat pipe is inserted into the first hole, and an end of the second heat pipe is inserted into the second hole.

3. The foldable electronic device of claim 2, wherein the heat conducting member has a tapered bending portion.

4. The foldable electronic device of claim 1, wherein the heat conducting member is a U-shaped heat pipe, an end of the first heat pipe has a first hole, an end of the second heat pipe has a second hole, an end of the heat conducting member is inserted into the first hole, and another end of the heat conducting member is inserted into the second hole.

5. The foldable electronic device of claim 4, wherein the heat conducting member has a tapered bending portion.

6. The foldable electronic device of claim 1, wherein the heat conducting member comprises a first sleeve, a second sleeve and a base, the first sleeve and the second sleeve are disposed on the base, an end of the first heat pipe is inserted into the first sleeve, and an end of the second heat pipe is inserted into the second sleeve.

7. The foldable electronic device of claim 1, wherein the heat conducting member is a metal block, the heat conducting member has a first hole and a second hole, an end of the first heat pipe is inserted into the first hole, and an end of the second heat pipe is inserted into the second hole.

8. The foldable electronic device of claim 1, wherein the heat conducting member is a vapor chamber, the heat conducting member has a first hole and a second hole, an end of the first heat pipe is inserted into the first hole, and an end of the second heat pipe is inserted into the second hole.
